(19) United States
(12) Patent Application Publication
(10) Pub. No.: US 2015/0255257 A1
(43) Pub. Date: Sep. 10, 2015

(54) SUBSTRATE COOLING MEMBER, SUBSTRATE PROCESSING DEVICE, AND SUBSTRATE PROCESSING METHOD

(71) Applicant: TOKYO ELECTRON LIMITED, Minato-ku, Tokyo (JP)

(72) Inventors: Atsushi Kawabe, Yamanashi (JP); Sensho Kobayashi, Yamanashi (JP)

(73) Assignee: TOKYO ELECTRON LIMITED, Minato-ku, Tokyo (JP)

(21) Appl. No.: 14/440,487

(22) PCT Filed: Oct. 25, 2013
(86) PCT No.: PCT/JP2013/079652

§ 371 Date: May 4, 2015

(30) Foreign Application Priority Data
Nov. 7, 2012 (JP) 2012-245360
Jun. 11, 2013 (JP) 2013-122587

(51) Int. Cl. H01J 37/32

(52) U.S. Cl. CPC H01J 37/32724; H01J 37/32733; H01J 37/32816; H01J 37/32834; H01J 37/32899; H01J 2237/002; H01J 2237/334

(57) ABSTRACT

An objective of the present invention is to simplify a configuration of a processing chamber for cooling a substrate in a substrate processing device. In a plasma processing device (10) whereby a plasma process is carried out upon a wafer (W), the wafer (W) which is plasma processed is conveyed into a load-lock chamber (13), and gas is discharged from a gas discharge member (25) upon the surface of the wafer (W), cooling the wafer (W). The gas discharge member (25) comprises a structure wherein a plurality of gas discharge nozzles (35) are formed in one flat plate face of a flat plate member (31). The gas discharge nozzles (35) comprise cylindrical eddy generating chambers (41), and nozzle holes (42) which are opened in bottom walls (52) of the eddy generating chambers (41) and discharge the gas. The flat plate face of the wafer (W) and the flat plate face wherein the gas discharge nozzles (35) are formed in the flat plate member (31) are positioned in parallel at a prescribed gap. A purge gas is discharged from the nozzle holes (42) toward the wafer (W), and a flow of an eddy is made to arise in the discharged purge gas, thereby cooling the wafer (W), and simultaneously switching the interior of the load-lock chamber (13) from a vacuum environment to an atmospheric pressure environment.

### TECHNICAL FIELD

The present disclosure relates to a substrate cooling member that cools a substrate such as, for example, a semiconductor wafer, a substrate processing apparatus including the substrate cooling member, and a substrate processing method using the substrate cooling member.

### BACKGROUND

A substrate processing apparatus known in the related art includes a vacuum processing chamber that processes a substrate such as, for example, a semiconductor wafer, in a vacuum (decompressed) atmosphere and at a high temperature. In the substrate processing apparatus, it is required to cool a substrate processed in the vacuum processing chamber to a predetermined temperature and to carry the substrate out to the outside which is under an atmospheric pressure (e.g., a container that accommodates a plurality of substrates). Thus, the following process has been known.

That is, the substrate processed in vacuum processing chamber is carried into an intermediate conveyance chamber, which is maintained at a vacuum atmosphere so as to place substrates therein, by a conveyance apparatus provided in a conveyance chamber maintained at a vacuum atmosphere (hereinafter, referred to as a “vacuum conveyance chamber), and is placed on a cooling table disposed in the intermediate conveyance chamber. Here, the intermediate conveyance chamber is arranged between the vacuum conveyance chamber and another conveyance chamber maintained at the atmospheric pressure (hereinafter, referred to as an “atmospheric conveyance chamber”). The intermediate conveyance chamber is configured such that its atmosphere is capable of being isolated from or communicated with the conveyance chambers.

After the substrate processed in the vacuum processing chamber is carried into the intermediate conveyance chamber which is isolated from the atmospheric conveyance chamber to be maintained at the vacuum atmosphere, the intermediate conveyance chamber is also isolated from the vacuum conveyance chamber and a purge gas such as, for example, nitrogen gas, is introduced into the intermediate conveyance chamber to return the interior of the intermediate conveyance chamber to the atmospheric pressure, during which the substrate is cooled by a cooling plate. When the interior of the intermediate conveyance chamber becomes the atmospheric pressure and the substrate is also fully cooled, the intermediate conveyance chamber and the atmospheric conveyance chamber are communicated with each other while the isolation state between the intermediate conveyance chamber and the vacuum conveyance chamber is maintained, and the substrate is taken out from the intermediate conveyance chamber and carried into a substrate accommodating container by a conveyance apparatus provided in the atmospheric conveyance chamber (see, e.g., Patent Document 1).

### PRIOR ART DOCUMENT

### Patent Document

Patent Document 1: Japanese Patent Laid-Open Publication No. 2010-182906

### SUMMARY OF THE INVENTION

### Problems to be Solved

In the relate art, the substrate is cooled by making cooling water flow in the cooling table where the substrate is placed using a time until the interior of the intermediate conveyance chamber is turned into the atmospheric pressure from the vacuum atmosphere. In the substrate processing apparatus that requires a cooling system including the cooling table as described above, there are problems in that the structure is complicated and the volume of the intermediate conveyance chamber increases to enlarge the apparatus. There is also a problem in that, due to the necessity of the cooling system, the costs of the substrate processing apparatus increase.

Conventionally, the purge gas introduced into the intermediate conveyance chamber in order to switch the interior of the intermediate conveyance chamber from the vacuum atmosphere to the atmospheric pressure has been used only for switching the interior of the intermediate conveyance chamber from the vacuum atmosphere to the atmospheric pressure. Thus, if the purge gas may be used for cooling the substrate, a configuration, which does not require a cooling apparatus such as, for example, the cooling table, may be simply implemented. Meanwhile, conventionally, the purge gas is introduced into the intermediate conveyance chamber through a brake filter in order to suppress particles within the intermediate conveyance chamber from being attached to the substrate by being blown up by the purge gas. However, if the purge gas may be introduced into the intermediate conveyance chamber without using the brake filter, the costs of the substrate processing apparatus may be reduced.

In the intermediate conveyance chamber, when a substrate processed in the vacuum processing chamber and heated to a predetermined temperature is placed on the cooling table, the substrate is delivered between a substrate conveyance apparatus that conveys the substrate and a lifting pin provided on the cooling table. In a state where the lifting pin supports the substrate, the peripheral portion of the substrate may be sagged more downwardly than the central portion of the substrate (i.e., in an upwardly convex arc shape) due to the weight of the substrate itself. Further, the central portion of the substrate is hardly cooled compared to the peripheral portion. Thus, when the substrate is placed on the cooling table in the arc shape and held in that state, the peripheral portion, which is easily cooled, is in contact with the cooling table to be further cooled, but the central portion is in a floating state from the cooling table not to be cooled, so that a temperature distribution generated on the substrate increases, which may cause deformation on the substrate. The deformation of the substrate may generate scratch on the rear surface of the substrate and damage a pattern (element) formed on the front surface of the substrate.

It is considered that the problems described above have become pronounced due to enlargement of substrates in recent years. As a method for handling these problems, a method of delaying the substrate cooling rate is considered, but in this method, throughput is reduced (productivity is lowered). Thus, what is demanded is a method of rapidly cooling a substrate while suppressing the deformation of the substrate.

An object of the present disclosure is to provide a substrate processing apparatus provided with a processing chamber for cooling a substrate in which the configuration of the processing chamber is capable of being simplified and miniaturized. Another object of the present disclosure is to provide a substrate processing apparatus which is capable cooling a substrate while suppressing deformation of the substrate without degrading throughput. Still another object of the present disclosure is to provide a substrate cooling member disposed in a processing chamber so as to cool a substrate and to provide a substrate processing method using the substrate cooling member.

### Means to Solve the Problems

In order to solve the problems described above, according to the present disclosure, there is provided a substrate cooling member including a plurality of gas injection nozzles formed on one flat plate face of the substrate cooling member which has a flat plate shape. The plurality of gas injection nozzles are configured to inject a gas toward a substrate so as to cool the substrate. Each of the plurality of gas injection nozzles includes: a cylindrical space which is opened in the one flat plate face of the substrate cooling member; and a nozzle hole which is opened in a circular bottom wall that defines the space, to inject the gas toward the space. When the gas is injected toward the substrate from the nozzle hole through the space in a state where the one flat plate face, which is formed with the plurality of gas injection nozzles in the substrate cooling member, faces a flat plate face of the substrate, a swirling flow is generated in the gas injected from the nozzle hole within the space so as to cool the substrate.

In the present disclosure the gas injected from the nozzle hole may generate a flow swirling in a plane orthogonal to the one flat plate face in the space.

In the present disclosure, the nozzle hole may inject the gas in a direction substantially orthogonal to the bottom wall that defines the space.

In the present disclosure, a portion where a side wall and the bottom wall that define the space intersect with each other is formed as a curved face having a predetermined curvature.

In the present disclosure, a protrusion may be formed at a center of the circular bottom wall that defines the space to protrude to the space, and the nozzle hole may be opened in the protrusion.

In the present disclosure, a portion where the bottom wall that defines the space and a side wall of the protrusion intersect with each other is formed as a curved face having a predetermined curvature.

In the present disclosure, assuming that a diameter of the space is D, a depth of the space is h, and a clearance between the one flat plate face formed with the gas injection nozzle and the flat plate face of the substrate is CL, a relation of 1.63<D/(h+CL)<2.57 is achieved.

In the present disclosure, the substrate cooling member may further includes a buffer chamber communicated with the plurality of nozzle holes, in which a gas supplied to the buffer chamber may be injected from the plurality of nozzle holes.

In the present disclosure, the buffer chamber may be divided to a plurality of blocks by a partition, and gas support ports may be formed to independently supply a gas to the plurality of blocks, respectively.

In the present disclosure, the plurality of blocks may be a first block facing a central portion of the substrate and a second block provided in outer periphery of the first block.

In the present disclosure, the plurality of gas injection nozzles may be provided in a region facing a central portion of the substrate.

In order to solve the problems described above, according to the present disclosure, there is provided a substrate processing apparatus including: a substrate processing chamber in which a predetermined processing accompanying a substrate temperature rise is performed on a substrate; and a substrate cooling chamber in which the substrate processed in the substrate processing chamber is cooled. The substrate cooling chamber includes: a support member configured to support the substrate, and a substrate cooling member including a plurality of gas injection nozzles formed on one flat plate face of the substrate cooling member which has a flat plate shape. The plurality of gas injection nozzles are configured to inject a gas toward the substrate supported on the support member to cool the substrate. Each of the plurality of gas injection nozzles includes: a cylindrical space which is opened in the one flat plate face of the substrate cooling member, and a nozzle hole which is opened in a circular bottom wall that defines the space, to inject the gas toward the space. When the gas is injected toward the substrate from the nozzle hole through the space in a state where the one flat plate face, which is formed with the plurality of gas injection nozzles in the substrate cooling member, faces a flat plate face of the substrate, a swirling flow is generated in the gas injected from the nozzle hole within the space so as to cool the substrate.

In the present disclosure, the substrate cooling chamber may be configured such that an interior of the substrate cooling chamber is configured to be selectively switched to an atmospheric pressure atmosphere or a vacuum atmosphere, so as to convey the substrate between a processing chamber which is under a vacuum atmosphere and a processing chamber which is under an atmospheric atmosphere. The substrate cooling member may be configured to inject a gas, which is introduced into the substrate cooling chamber in order to switch the substrate cooling chamber from the vacuum atmosphere to the atmospheric pressure atmosphere, from the plurality injection nozzles to cool the substrate.

In the present disclosure, the processing chamber which is under the vacuum atmosphere may be the substrate processing chamber or a first substrate conveyance chamber disposed between the substrate processing chamber and the substrate cooling chamber in which a first conveyance apparatus is disposed to convey the substrate between the processing chamber and the substrate cooling chamber, and the processing chamber which is under the atmospheric atmosphere may be a second substrate conveyance chamber in which a second conveyance apparatus is disposed to convey the substrate between a container accommodating the substrate and the substrate cooling chamber.

In order to solve the problems described above, according to the present disclosure, there is provided a substrate processing apparatus including: a substrate processing chamber maintained under a vacuum atmosphere, and configured to perform a predetermined processing accompanying a substrate temperature rise on a substrate accommodated therein; a substrate carry-in chamber maintained under an atmospheric pressure atmosphere, in which the substrate to be processed in the substrate processing chamber is carried into the substrate carry-in chamber from outside; and an intermediate conveyance chamber having an interior configured to be selectively switched to the atmospheric pressure atmosphere or the vacuum atmosphere so as to carry the substrate between the processing chamber which is under the vacuum atmosphere and the substrate carry-in chamber which is under the atmospheric atmosphere. The intermediate conveyance chamber includes: a support member configured to support the substrate; a substrate cooling member including a plurality of gas injection nozzles formed on one flat plate face of the substrate cooling member which has a flat plate shape. The plurality of gas injection nozzles are configured to inject a gas toward a substrate supported on the support member. Each of the plurality of gas injection nozzles includes: a cylindrical space which is opened in the one flat plate face of the substrate cooling member, and a nozzle hole which is opened in a circular bottom wall that defines the space, to inject the gas toward the space. When the gas is injected toward the substrate from the nozzle hole through the space in a state where the one flat plate face, which is formed with the plurality of gas injection nozzles in the substrate cooling member, faces a flat plate face of the substrate, a swirling flow is generated in the gas injected from the nozzle hole within the space so as to cool the substrate, and at the same time, the intermediate conveyance chamber is switched from the vacuum atmosphere to the atmospheric pressure atmosphere.

In the present disclosure, the substrate processing chamber may be a plasma processing chamber configured to perform a plasma processing on the substrate.

In the present disclosure, the gas injected from the nozzle hole may generate a flow swirling in a plane orthogonal to the one flat plate face in the space.

In the present disclosure, the nozzle hole may inject the gas in a direction substantially orthogonal to the bottom wall that defines the space.

In the present disclosure, each of the plurality of gas injection nozzles may include a protrusion formed to protrude to the space at a center of the circular bottom wall that defines the space, and the nozzle hole may be opened in the protrusion.

In the present disclosure, assuming that a diameter of the space is D, a depth of the space is h, and a clearance between the one flat plate face formed with the gas injection nozzle and the flat plate face of the substrate is CL, a relation of 1.63<D/(h+CL)<2.57 may be achieved.

In the present disclosure, the substrate cooling member may include a buffer chamber communicated with the plurality of nozzle holes, and a gas supplied to the buffer chamber may be injected from the plurality of nozzle holes.

In the present disclosure, the buffer chamber may be divided to a plurality of blocks by a partition, and gas support ports may be formed to independently supply a gas to the plurality of blocks, respectively.

In the present disclosure, the plurality of blocks may be a first block facing a central portion of the substrate and a second block provided in outer periphery of the first block.

In the present disclosure, the buffer chamber may be divided into a plurality of blocks and a gas supply unit configured to control a gas flow rate supplied to the plurality of blocks may be provided such that a flow speed of the gas injected from the gas injection nozzles facing the central portion of the substrate supported on the support member among the plurality of gas injection nozzles is different from a flow rate of the gas injected from the gas injection nozzles facing the peripheral portion of the substrate.

In the present disclosure, the plurality of gas injection nozzles may be provided in a region facing a central portion of the substrate.

In the present disclosure, the flat plate face of the substrate cooling member may have a size substantially equal to a size of the flat plate face of the substrate supported on the support member.

In order to solve the problems described above, according to the present disclosure, there is provided a substrate processing method that cools a substrate by injecting a gas toward the substrate from a plurality of gas injection nozzles using a substrate cooling member including the plurality of gas injection nozzles formed on one flat plate face of the substrate cooling member which has a flat plate shape. The gas is injected toward the substrate from the gas injection nozzles in a state where the one flat plate face, which is formed with the plurality of gas injection nozzles in the substrate cooling member, faces a flat plate face of the substrate, and a swirling flow is generated in the gas in a plane orthogonal to the flat plate face of the substrate to cool the substrate.

In the present disclosure, a cylindrical space may be formed such that the plurality of gas injection nozzles are opened in the one flat plate face of the substrate cooling member, and the plurality of gas injection nozzles may be opened in a circular bottom wall defining the space to form nozzles holes that inject the gas toward the space such that the swirling flow is generated in the space.

In the present disclosure, the gas may be injected toward the substrate from the plurality of gas injection nozzles using the substrate cooling member which is provided with the plurality of gas injection nozzles in a region facing a central portion of the substrate.

In the present disclosure, the central portion of the substrate may have a radius within a range of ½ of a radius of the substrate from a center of the substrate.

In the present disclosure, the substrate cooling member may be disposed within a processing chamber configured to be selectively switched to an atmospheric pressure atmosphere or vacuum atmosphere, and the gas may be injected from the plurality of gas injection nozzles in the processing chamber which is under the vacuum atmosphere so that the substrate is cooled and at the same time, an interior of the processing chamber is switched to the atmospheric pressure atmosphere.

In the present disclosure, while the gas is injected from the plurality of gas injection nozzles toward the substrate in a state where the substrate is supported on a support member provided in the processing chamber, the support member may be moved down into a cooling table provided in the processing chamber so that the substrate is placed on the cooling table to be cooled.

In the present disclosure, cooling water is circulated in the cooling table.

### Effect of the Invention

In the present disclosure, the gas is injected toward a substrate from the substrate cooling member, and a swirling flow is generated in the injected gas so that the substrate is efficiently cooled. This makes a conventional water cooling system needless which enables simplification of the structure of the processing chamber for cooling the substrate so that the processing chamber may be miniaturized. Further, miniaturization and cost reduction of the substrate processing apparatus become possible. In addition, in the case of the substrate processing apparatus which is provided with the processing chamber, of which the atmosphere is adjusted between a vacuum atmosphere and an atmospheric pressure atmosphere, the purge gas introduced into the processing chamber when the processing chamber is switched from the vacuum atmosphere to the atmospheric pressure atmosphere may be used for cooling the substrate. This makes the brake filter, which has been conventionally required for introducing a purge gas into a processing chamber, needless and thus, enables cost reduction of the substrate processing apparatus. In the present disclosure, a plurality of gas injection nozzles are provided in a region facing a central portion of the substrate so as to inject the gas to the substrate. This assists the cooling of the central portion of the substrate which is hardly cooled as compared to the peripheral portion of the substrate. Thus, it is possible to cool the substrate while suppressing deformation of the substrate without degrading throughput.

### BRIEF DESCRIPTION OF THE DRAWINGS

FIG. 1 is a plan view illustrating a schematic configuration of a plasma processing apparatus according to an exemplary embodiment of the present disclosure.

FIG. 2 is a cross-sectional view illustrating a schematic configuration of a load-lock chamber provided in the plasma processing apparatus of FIG. 1.

FIG. 3A is a perspective view illustrating a configuration of a gas injection member disposed in the load-lock chamber of FIG. 2.

FIG. 3B is a cross-sectional view illustrating the configuration of the gas injection member disposed in the load-lock chamber of FIG. 2.

FIG. 4 is a cross-sectional view illustrating a configuration of a gas injection nozzle provided in the gas injection member of FIGS. 3A and 3B.

FIG. 5 is a view schematically illustrating flows of a purge gas injected from the gas injection nozzle of FIG. 4.

FIG. 6 is a view illustrating a result obtained by confirming the flows of the purge gas illustrated in FIG. 5 through simulation.

FIG. 7 is a view illustrating another result obtained by confirming the flows of the purge gas illustrated in FIG. 5 through simulation.

FIG. 8 is a view illustrating still another result obtained by confirming the flows of the purge gas illustrated in FIG. 5 through simulation.

FIG. 9 is a view illustrating still another result obtained by confirming the flows of the purge gas illustrated in FIG. 5 through simulation.

FIG. 10 is a view illustrating still another result obtained by confirming the flows of the purge gas illustrated in FIG. 5 through simulation.

FIG. 11 is a view illustrating still another result obtained by confirming the flows of the purge gas illustrated in FIG. 5 through simulation.

FIG. 12 is a view illustrating yet another result obtained by confirming the flows of the purge gas illustrated in FIG. 5 through simulation.

FIG. 13 is a view illustrating yet another result obtained by confirming the flows of the purge gas illustrated in FIG. 5 through simulation.

FIG. 14 is a view illustrating yet another result obtained by confirming the flows of the purge gas illustrated in FIG. 5 through simulation.

FIG. 15 is a view illustrating yet another result obtained by confirming the flows of the purge gas illustrated in FIG. 5 through simulation.

FIG. 16 is a cross-sectional view schematically illustrating a schematic configuration of a modified example of the gas injection member of FIGS. 3A and 3B.

FIG. 17A is a cross-sectional view schematically illustrating a schematic configuration of another modified example of the gas injection member of FIGS. 3A and 3B and a method of cooling a wafer.

FIG. 17B is a cross-sectional view illustrating a schematic configuration of another modified embodiment of the gas injection member of FIGS. 3A and 3B and a method of cooling a wafer.

FIG. 17C is a cross-sectional view illustrating a schematic configuration of another modified embodiment of the gas injection member of FIGS. 3A and 3B and a method of cooling a wafer.

FIG. 18A is a cross-sectional view illustrating a schematic configuration of a modified example of the gas injection nozzle of FIG. 4.

FIG. 18B is a cross-sectional view illustrating a schematic configuration of a modified example of the gas injection nozzle of FIG. 4.

FIG. 18C is a cross-sectional view illustrating a schematic configuration of a modified example of the gas injection nozzle of FIG. 4.

### DETAILED DESCRIPTION TO EXECUTE THE INVENTION

Hereinafter, exemplary embodiments of the present disclosure will be described in detail with reference to the accompanying descriptions. Here, as a substrate processing apparatus according to the present disclosure, a plasma processing apparatus that performs a plasma processing on a semiconductor wafer (hereinafter, referred to as a “wafer”) will be discussed.

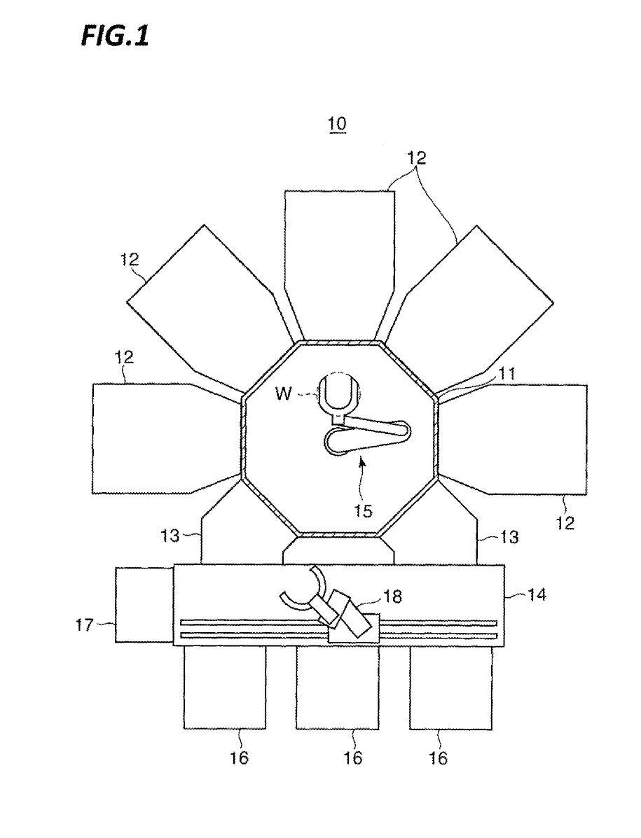

FIG. 1 is a plan view illustrating a schematic configuration of a plasma processing apparatus 10 according to an exemplary embodiment of the present disclosure. The plasma processing apparatus 10 is provided with three load ports 16 provided to dispose FOUPs (not illustrated) which are carriers that accommodate a predetermined number of wafers W having a diameter of 450 mm.

In the plasma processing apparatus 10, a loader module 14 is disposed adjacent to the load ports 16 so as to perform carry-in/carry-out of the wafers with respect to the FOUPS, and a positioning mechanism 17 is disposed adjacent to the loader module 14 so as to perform positioning of the wafers W. In addition, two load-lock chambers 13 are disposed at a side opposite to the load ports 16 with the loader module 14 being interposed therebetween. The interior of the loader module 14 is always under an atmospheric pressure atmosphere, and a wafer conveyance apparatus 18 is disposed within the loader module 14. The wafer conveyance apparatus 18 conveys wafers W among the FOUPs disposed in the load ports 16, the positioning mechanism 17, and the load-lock chambers 13.

The load-lock chambers 13 are configured to switch the interiors thereof between the vacuum atmosphere and the atmospheric pressure atmosphere, and the interiors of the load-lock chambers 13 become the atmospheric pressure atmosphere when they are communicated with the loader module 14, and become the vacuum atmosphere when they are communicated with the vacuum conveyance chamber 11 to be described later. Meanwhile, the detailed configuration of the load-lock chambers 13 will be described later.

A vacuum conveyance chamber 11, which has an octagonal shape in a plan view, is disposed at the side opposite to the, loader module 14 with the load-lock chambers 13 being interposed therebetween, and five vacuum processing chambers are radially disposed around the vacuum conveyance chamber 11 to be connected with the vacuum conveyance chamber 11. The interior of the vacuum conveyance chamber 11 is always maintained at a predetermined vacuum degree, and a scalar robot 15 is disposed therein so as to convey the wafers W. In addition, the interior of each of the vacuum processing chambers 12 is maintained at a predetermined vacuum degree. The vacuum processing chambers accommodate wafers W therein to perform a predetermined plasma processing such as, for example, a plasma etching processing.

Meanwhile, although not illustrated in FIG. 1, gate valves are disposed between respective units (the vacuum conveyance chamber 11, the vacuum processing chambers 12, the load-lock chambers 13, the loader module 14, the load ports 16, and the positioning mechanism 17), and the gate valves perform an opening/closing operation as needed. The load-lock chambers 13 serve as an intermediate conveyance chamber for conveying the wafers between the loader module 14 and the vacuum conveyance chamber 11 and as a substrate cooling chamber for cooling the wafers W processed in the vacuum processing chambers 12.

In the plasma processing apparatus 10, a plasma processing is performed on a wafer W in the following order. A plurality of wafers W are simultaneously processed in the plasma processing apparatus 10. Here, however, descriptions will be made on a processing of one wafer W according to a time sequence.

First, when a FOUP is disposed in a load port 16, a gate valve provided in the load port 16 holds and opens the closure of the FOUP, the wafer conveyance apparatus 18 takes out a wafer W from the FOUP, and holds and carries the wafer W into the positioning mechanism 17. The wafer W positioned by the positioning mechanism 17 is carried into a load-lock chamber 13, which is maintained at the atmospheric pressure atmosphere, by the wafer conveyance apparatus 18. At this time, the vacuum conveyance chamber 11 side gate valve of the load-lock chamber 13 is closed. After the loader module 14 side gate valve of the load-lock chamber 13 is closed, the load-lock chamber 13 is decompressed to a predetermined vacuum degree.

When the interior of the load-lock chamber 13 reaches the predetermined vacuum degree, the vacuum conveyance chamber 11 side gate valve is opened, and the scalar robot 15 carries the wafer W out of the load-lock chamber 13 and carries the held wafer W into a vacuum processing chamber 12 so that a predetermined plasma processing is performed on the wafer W in the vacuum processing chamber 12. After the processing in the vacuum processing chamber 12 is terminated, the wafer W has a temperature raised by the plasma processing. The wafer W having the raised temperature is carried out from the vacuum processing chamber 12 and carried into the load-lock chamber 13 by the scalar robot 15. The vacuum conveyance chamber 11 side gate valve of the load-lock chamber 13 is closed, and a purge gas such as, for example, nitrogen gas, is introduced into the load-lock chamber 13 so as to develop the atmospheric pressure atmosphere in the load-lock chamber 13. In the present exemplary embodiment, the purge gas is used for cooling the wafer W. This will be described in detail below.

When the interior of the load-lock chamber 13 becomes the atmospheric pressure atmosphere and the wafer W is cooled to the predetermined temperature, the loader module 14 side gate valve of the load-lock chamber 13 is opened, and the wafer conveyance apparatus 18 takes out the wafer W from the load-lock chamber 13 and carries the wafer W into a predetermined position of the FOUP. In this way, the processing performed on the wafer W in the plasma processing apparatus 10 is terminated.

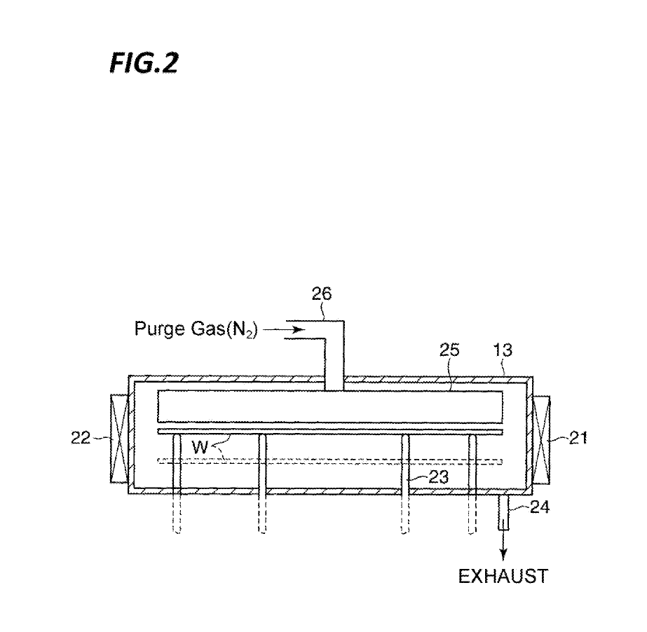

FIG. 2 is a cross-sectional view illustrating a schematic configuration of a load-lock chamber 13 provided in the plasma processing apparatus of FIG. 1. At the vacuum conveyance chamber 11 side of the load-lock chamber 13, a gate valve 21 is disposed, and at the loader module 14 side of the load-lock chamber 13, a gate valve 22 is disposed. An exhaust pipe 24 is connected to the bottom wall of the load-lock chamber 13, and an exhaust apparatus (not illustrated) such as, for example, a vacuum pump, is connected to the exhaust pipe 24. When the exhaust apparatus is driven, the interior of the load-lock chamber 13 may be decompressed to a predetermined vacuum degree through the exhaust pipe 24.

Lifting pins 23 serving as support members for supporting a wafer W are provided to be capable of being moved up and down by a lifting device (not illustrated) through the bottom wall of the load-lock chamber 13 in the vertical direction (in the direction orthogonal to the bottom wall). Meanwhile, illustration of a vacuum sealing structure around the lifting pins 23 is omitted in FIG. 2. Further, the number of lifting pins 23 is set to three or more so as to stably support the wafer W. The lifting pins 23 are moved up and down between a position indicated by dotted lines (delivery position) where the lifting pins 23 perform delivery of the wafer W with the wafer conveyance apparatus 18 provided in the loader module 14 or the scalar robot 14 provided in the vacuum conveyance chamber 11, and a position indicated by solid lines (cooling treatment position) where the wafer W is cooled by a gas injection member 25 (described below) having a flat plate shape.

The gas injection member 25 serving as a substrate cooling member is disposed at the ceiling side within the load-lock chamber 13. The gas injection member 25 is supplied with a purge gas such as, for example, nitrogen gas N₂, from a gas supply source (not illustrated) through a gas supply tube 26. The wafer W processed in the vacuum processing chamber 12 is carried into the load-lock chamber 13 and delivered to the lifting pins 23 so that the lifting pins 23 hold the wafer W at the cooling treatment position. When the gate valve 21 is closed, the gas injection member 25 injects the purge gas toward the wafer W supported on the lifting pins 23. As a result, heat exchange is performed between the purge gas and the wafer W so that the wafer W is cooled to a predetermined temperature, and at the same time, the interior of the load-lock chamber 13 is switched from the vacuum atmosphere to the atmospheric pressure atmosphere.

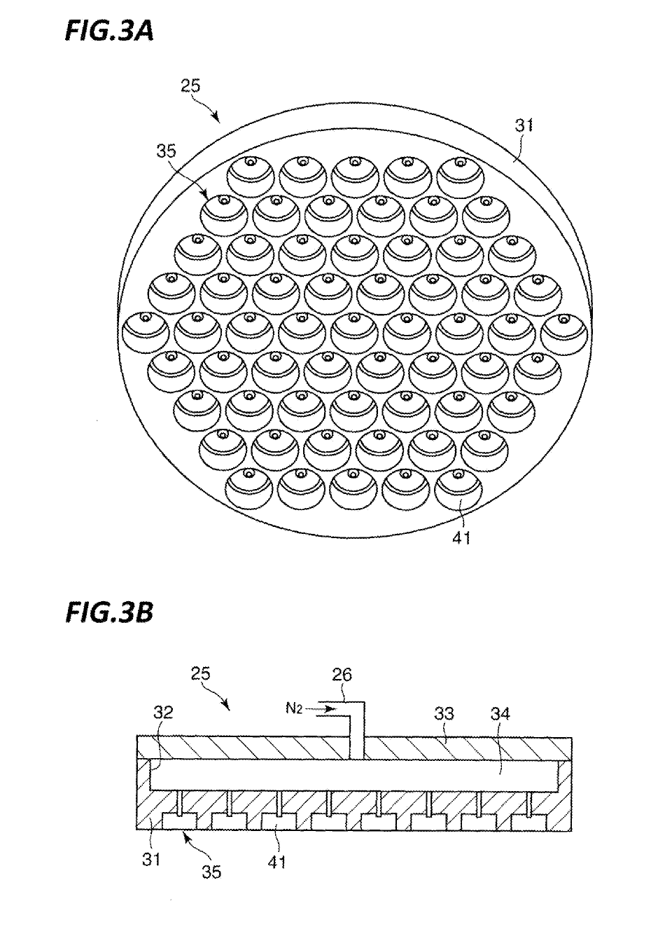

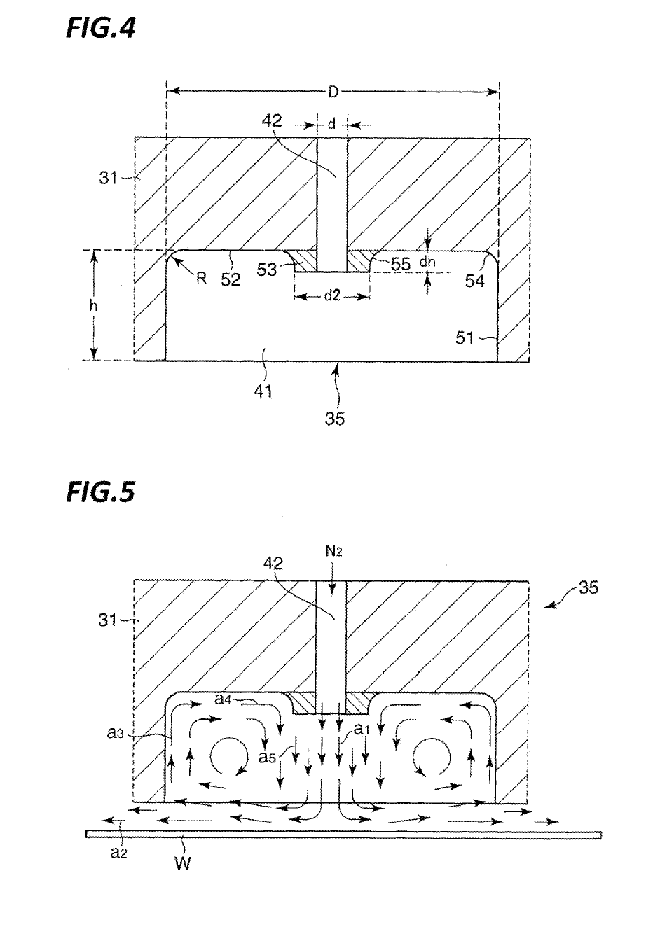

FIG. 3A is a perspective view illustrating a configuration of a gas injection member 25 disposed in the load-lock chamber of FIG. 2. In addition, FIG. 3B is a cross-sectional view illustrating the configuration of the gas injection member 25 disposed in the load-lock chamber of FIG. 2. The gas injection member 25 includes a flat-plate type disc member 31, and a plurality of gas injection nozzles 35 are formed on the bottom side which is one principal face (flat plate face) of the disc member 31 [the surface facing the principal face (flat plate face) of the wafer W]. Details of the structure of the gas injection nozzle 35 will be described below with reference to, for example, FIG. 4.

The disc member 31 may have a diameter which is the same as that of the wafer W, which allows the purge gas to be injected to the entire surface of the wafer W so as to cool the wafer W. FIGS. 3A and 3B illustrates a structure in which sixty one (61) gas injection nozzles 35 each having a vortex generating chamber 41—a cylindrical space having a diameter of 45 mm—are arranged at regular intervals at a 50 mm pitch, as an example.

A recess 32 is formed on the top face side of the disc member 31. The top face of the disc member 31 is covered by a disc-shaped cover member 33 so that a buffer chamber 34 is formed between the disc member 31 and the cover member 33. A gas supply tube 26 is attached to the cover member 33, and the purge gas supplied to the gas injection member 25 through the gas supply tube 26 is substantially uniformized in pressure within the buffer chamber 34 and then injected from the gas injection nozzles 35. Although FIG. 3B illustrates a structure in which the recess 32 and the gas injection nozzles 35 are formed in the single disc member 31, such a structure may be implemented by bonding a plurality of members.

FIG. 4 is a cross-sectional view illustrating a configuration of a gas injection nozzle 35 provided in the gas injection member FIGS. 3A and 3B. The gas injection nozzle 35 includes a side wall 51 and a bottom wall 52 that define a vortex generating chamber 41 which is a cylindrical space. The side wall 51 forms a cylindrical surface of the vortex generating chamber 41 and is orthogonal to the bottom face of the disc member 31, and the bottom wall 52 has a circular shape, and is orthogonal to the side wall 51 (parallel with the bottom face of the disc member 31). A protrusion 53 protruding toward the vortex generating chamber 41 is formed at the center of the bottom wall 52. In addition, a nozzle hole 42 is formed through the protrusion 53 at the center of the bottom wall 52 in the direction orthogonal to the bottom wall 52 (in the vertical direction) so that the nozzle hole 42 is communicated with the buffer chamber 34.

In the gas injection nozzle 35, a region where the side wall 51 and the bottom wall 52 intersect with each other is formed in a curved face 54 having a predetermined curvature. Similarly, a region where the side wall of the protrusion 53 and the bottom wall 52 intersect with each other is formed in a curved face 55 having a predetermined curvature. Forming the protrusion 53 and the curved faces 54 and 55 is not necessarily required. However, as described below, forming the protrusion 53 and the curved faces 54 and 55 presents an effect of facilitating the generation of a vortex in the purge gas injected from the nozzle hole 42.

FIG. 5 is a view schematically illustrating flows of a purge gas injected from the gas injection nozzle 35 of FIG. 4. When the purge gas such as, for example, nitrogen gas, is injected in the vertical direction toward the wafer W from the nozzle hole 42 (arrows a1), a part of the purge gas impinging against the wafer W is discharged to the outside from a gap (clearance) between the bottom face of the gas injection member 25 and the wafer W (arrows a2). At the same time, a part of the purge gas moves up substantially in the vertical direction along the side wall 51 toward the bottom wall 52 (arrows a3), flows along the bottom wall 52 from the peripheral portion to the central portion of the bottom wall 52 (arrows a4), and follows the purge gas injected from the nozzle hole 42 to flow again in the vertical direction toward the wafer W (arrows a5).

In this way, the vortex of the purge gas including the vertical flows, that is, the flows of the purge gas swirling in a plane orthogonal to the surface of the wafer W is generated in the vortex generating chamber 41, and the wafer W is cooled by the heat exchange between the wafer W and the purge gas. By generating the vortex of the purge gas, the number of times of impingement of the purge gas against the wafer W may be increased until the purge gas is discharged from the clearance between the bottoms surface of the gas injection member 25 and the wafer W, so that the wafer W can be efficiently cooled using the purge gas. In such a case, when the flows of the purge gas forming the vortex are slow, the heat exchange may be efficiently performed.

Meanwhile, the “vortex of the purge gas” in the present exemplary embodiments neither indicates that the full amount of the purge gas should form the vortex, nor indicates that the purge gas should form a swirling flow that circulates many times, i.e. over a large number of times. The “vortex of the purge gas” refers to a flow of a purge gas, at least a part of which impinges against the wafer W again after the purge gas impinges against the wafer W and which is generated within the vortex generating chamber, as compared with a flow which is rapidly discharged from the surface of the wafer W after impinging against the wafer W.

As injection conditions of the purge gas from the nozzle hole 42 into the vortex generating chamber 41, for example, the vortex of the purge gas should be well formed uniformly within the vortex generating chamber 41, and the flow speed of the purge gas should not be excessively increased. The reason why the flow speed of the purge gas should not be excessively increased is that when the flow speed is excessively increased, the purge gas may be discharged from the clearance between the bottom face of the gas injection member 25 and the wafer W without sufficient heat exchange, and the purge gas discharged as such may wind up particles attached to, for example, the bottom wall of the load-lock chamber 13.

The shape of the gas injection nozzle 35 and the flow rate of the purge gas are properly determined so as to satisfy the conditions described above and also in consideration of the inner volume of the load-lock chamber 13 or the throughput of the plasma processing apparatus 10. The shape of the gas injection nozzle 35 and the flow rate of the purge gas are designed such that when the temperature of the wafer W is reduced from 250° C. to 150° C., a temperature falling rate of about 4° C./sec to about 9° C./sec is obtained. Thus, hereinafter, descriptions will be made on simulation results for purge gas flows which are helpful in designing the shape of the gas injection nozzle 35.

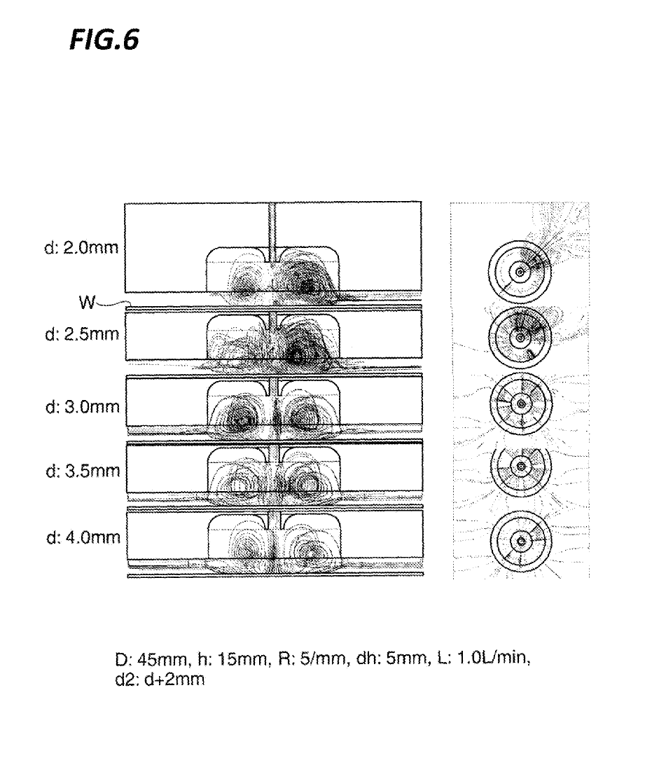

FIGS. 6 to 15 are views illustrating results obtained by confirming the flows of the purge gas illustrated in FIG. 5 for one gas injection nozzle 35 through simulation. In the original drawings of FIGS. 6 to 15, a difference in flow speed of the purge gas is expressed by a difference in color, and is represented as a gradation color change according to a variation of wavelength of visible light, for example, in a manner of indicating a portion, in which the flow speed is high, as red, indicating a portion, in which the flow speed is low, as blue, and indicating the portion therebetween as red, orange color, green, light blue, and blue, from the red toward the blue. However, in the accompanying drawings, the expression is limited to black and white. Thus, since FIGS. 6 to 15, which illustrate monochromatic views of the original drawings, may not clearly indicate flow speeds of the purge gas. For example, the red-colored portion, in which the flow speed is high, and the blue-colored portion, in which the flow speed is low, are similarly indicated as black, and the intermediate flow speed portion (yellow-yellow green-light blue) is difficult to indicate on the drawings. Thus, in the description of each of FIGS. 6 to 15, descriptions on a flow rate distribution of purge gas will be supplemented as necessary.

The parameters represented in respective drawings of FIGS. 6 to 15 correspond to the parameters represented in FIG. 4. That is, a diameter D represents the diameter of the vortex generating chamber 41, a height h represents the depth of the vortex generating chamber 41 (a length between the bottom wall 52 and the bottom face of the disc member 31), a tube diameter d represents the diameter of the nozzle hole 42, a curvature R represents a curvature of the curved faces 54 and 55, a protrusion height dh represents the height of the protrusion 53, and a protrusion diameter d2 represents the diameter of the top of the protrusion 53 (the external diameter at the gas injection port side). In addition, a flow speed L represents a flow rate of the purge gas injected from the nozzle hole 42, and the clearance (gap width) CL between the bottom face of the gas injection member 25 and the wafer W is set to 5 mm.

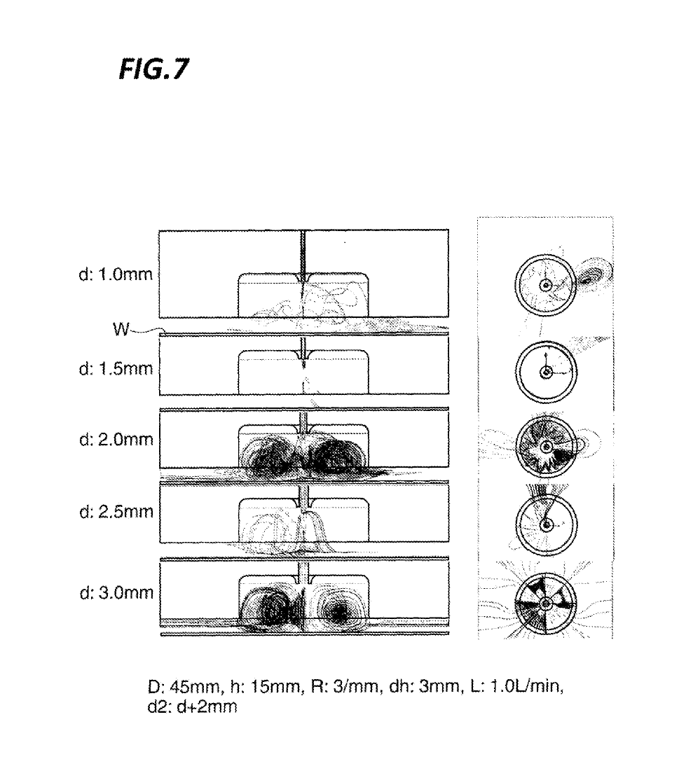

FIG. 6 illustrates a simulation result obtained by varying the tube diameter d in a range of 2 mm to 4 mm. Since the flow rate of purge gas is constant, the flow speed of the purge gas within the nozzle hole 42 is reduced as the tube diameter d of the nozzle hole 42 increases. Thus, from the relationship between the flow speed and the expressed colors in the original drawing, the flow speed lines of the purge gas within the nozzle hole 42 are expressed heavily when the tube diameter d of the nozzle hole 42 is small, and the flow speed lines are expressed lightly when the tube diameter d is large. After injected from the nozzle hole 42, the flow generated within the speed vortex generating chamber 41 and having a low flow speed is expressed heavily again. This is also applicable to FIG. 7.

The result obtained in the parameter condition represented in FIG. 6 is that when the tube diameter d is 2 mm or more and less than 3 mm, the generation of a favorable vortex having a low flow speed is shown within the vortex generating chamber 41. However, when the tube diameter d becomes equal to or larger than 3 mm, although a vortex is generated, the density of low flow speed lines of gas is reduced as illustrated, in which case it is estimated that the cooling efficiency is degraded.

In FIG. 6, the curvature R of the curved faces 54 and 55 is set to 5/mm and the protrusion height is set to 5 mm. Whereas, FIG. 7 illustrates a simulation result obtained by setting the curvature R to 3/mm and the protrusion height dh to 3 mm and varying the tube diameter d in a range of 1 mm to 3 mm. The result obtained in the parameter conditions represented in FIG. 7 is that when the tube diameter d is 2 mm or 3 mm, generation of a favorable vortex having a low flow speed is shown, but when the tube diameter d, which is determined as being favorable in the result of FIG. 6, is 2.5 mm, the vortex is hardly generated. From this result, it is considered that the tube diameter of the nozzle hole 42 capable of favorably generating a vortex in the purge gas is influenced by the tube diameter d of the nozzle hole 42, the curvature R, and the protrusion height dh.

Meanwhile, the gas flows, which are indicated approximately as yellow-yellow green-light blue in the original drawing as described above, are difficult to indicate on the drawing using flow speed lines. Thus, for example, in the case where the tube diameter d is 4 mm in FIG. 6 or in the case where the tube diameter d is 1 mm, 1.5 mm, or 2.5 mm in FIG. 7, the purge gas flowing out to the outside in a flow speed which does not substantially vary from the flow speed injected from the nozzle hole 42 is not expressed.

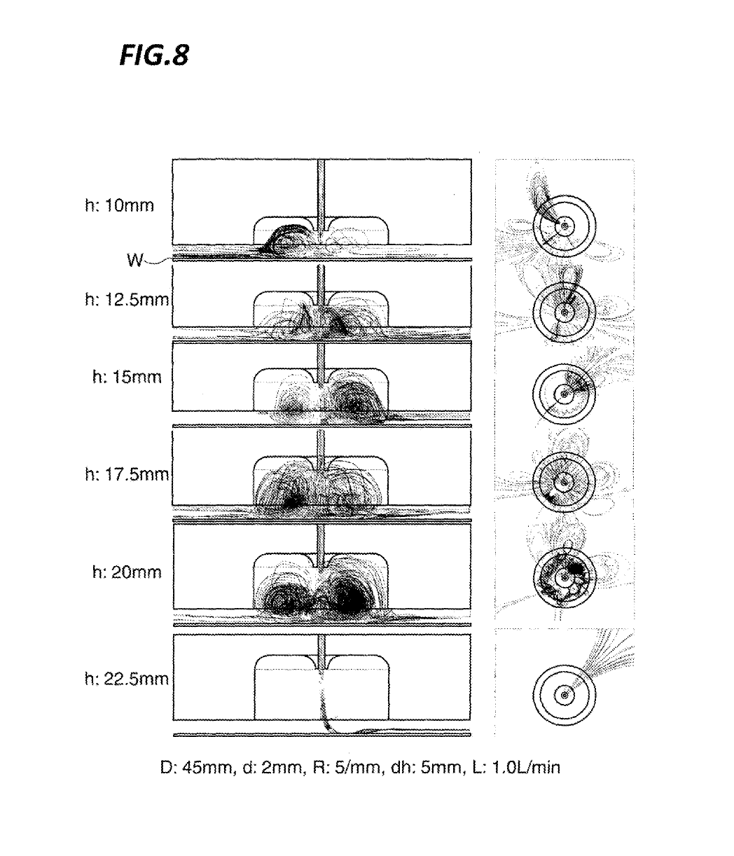

Meanwhile, in order to examine which parameter has an influence on the flow of the purge gas when simulating the flow of the purge gas, it is necessary to set the parameter as a variable parameter and then to fix the other parameters. For this reason, from the simulation results of FIGS. 6 and 7, it is determined that the tube diameter d is a parameter having an influence on the generation of a vortex of the purge gas. However, the simulation results of FIGS. 6 and 7 do not indicate that the tube diameter d in the gas injection nozzle 35 is always limited to 2 mm or more and less than 3 mm. The results illustrated in FIGS. 8 to 15 also show suitable conditions of variable parameters in which case predetermined parameters are fixed.

FIG. 8 illustrates a simulation result obtained by varying the depth h of the vortex generating chamber 41 in a range of 10 mm to 22.5 mm. The result obtained in the parameter condition represent in FIG. 8 is that in particular, when the depth h is 15 mm or more and 20 mm or less, a favorable vortex having a low flow speed is generated. Meanwhile, a state, in which the purge gas injected from the nozzle hole 42 and having a high flow speed is discharged as it is, is illustrated in the case where the depth h is 22.5 mm.

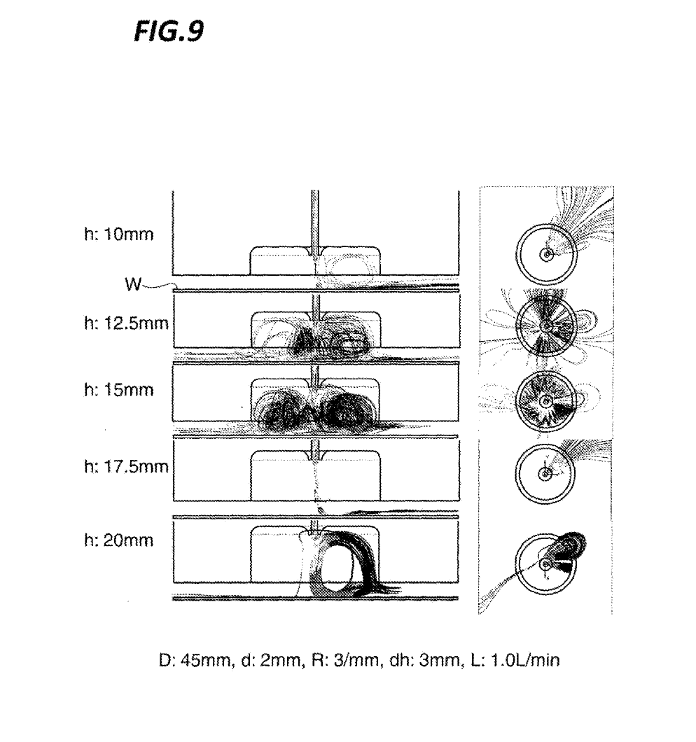

In FIG. 8, the curvature R of the curved faces 54 and 55 was set to 5/mm, and the protrusion height dh was set to 5 mm. Whereas, FIG. 9 illustrates a result of simulation in which the curvature R was set to 3/mm, the protrusion height dh was set to 3 mm, and the depth h was varied in the range of 10 mm to 20 mm. The result obtained in the parameter condition illustrated in FIG. 6 is that when the depth h is 12.5 mm or more and 15 mm or less, a favorable vortex having a low flow speed is generated. Upon comparing the respective results of FIGS. 8 and 9 with each other, it is considered that when the protrusion height dh is low and the curvature R is small, a vortex having a low flow speed may be generated even in a condition where the height h is low. Meanwhile, a state, in which the purge gas injected from the nozzle hole 42 and having a high flow speed is discharged as it is, is illustrated in the case where the depth h is 17.5 mm.

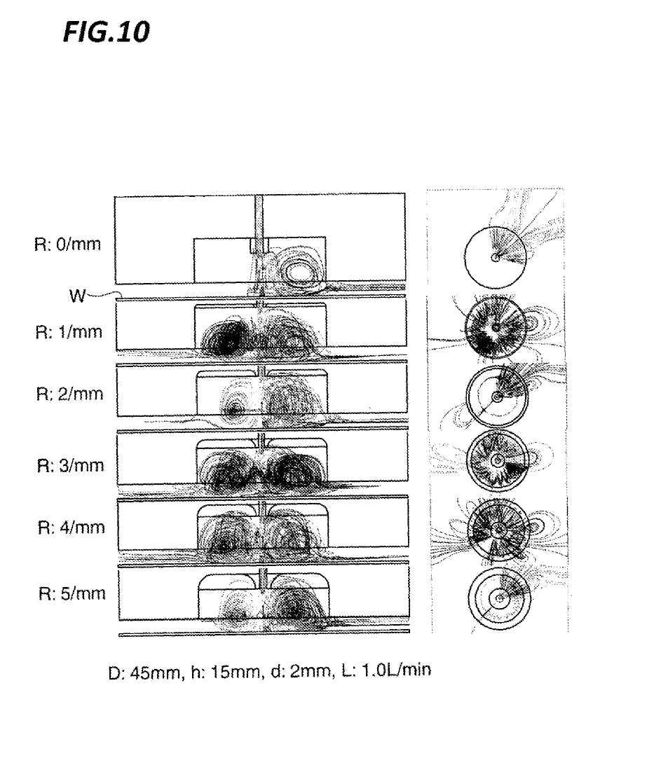

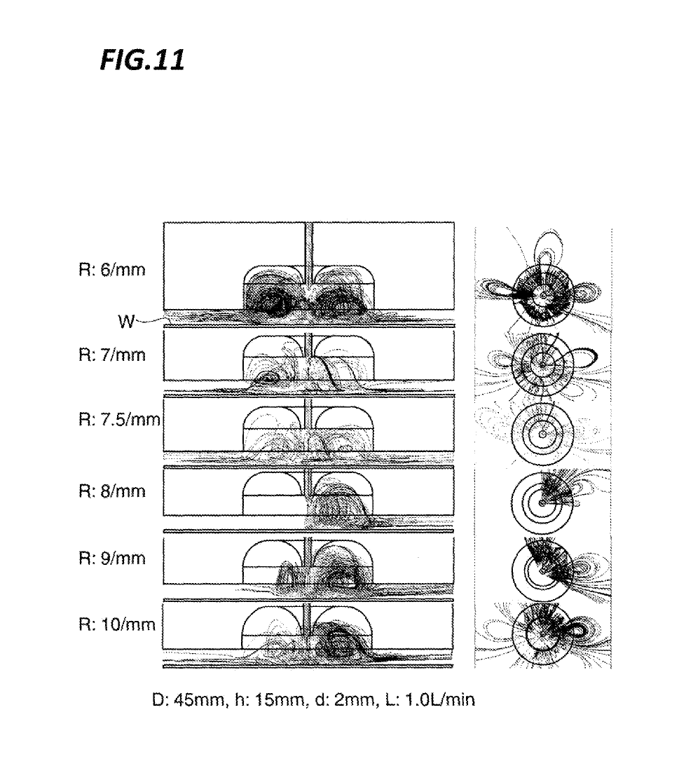

FIGS. 10 and 11 illustrate simulation results in which the curvature R was varied in a range of 0/mm to 10/mm, and the protrusion height dh was varied depending on the curvature R. Here, the protrusion height dh when the curvature R is 0/mm is set to 5 mm, and otherwise, the minimum height capable of forming the curved face having the curvature R is set as the protrusion height dh. For example, the protrusion height dh is 1 mm when the curvature R is 1/mm. In the parameter conditions illustrated in FIGS. 10 and 11, generation of a favorable vortex having a low flow speed is shown when the curvature R is 3/mm or more and 6/mm or less.

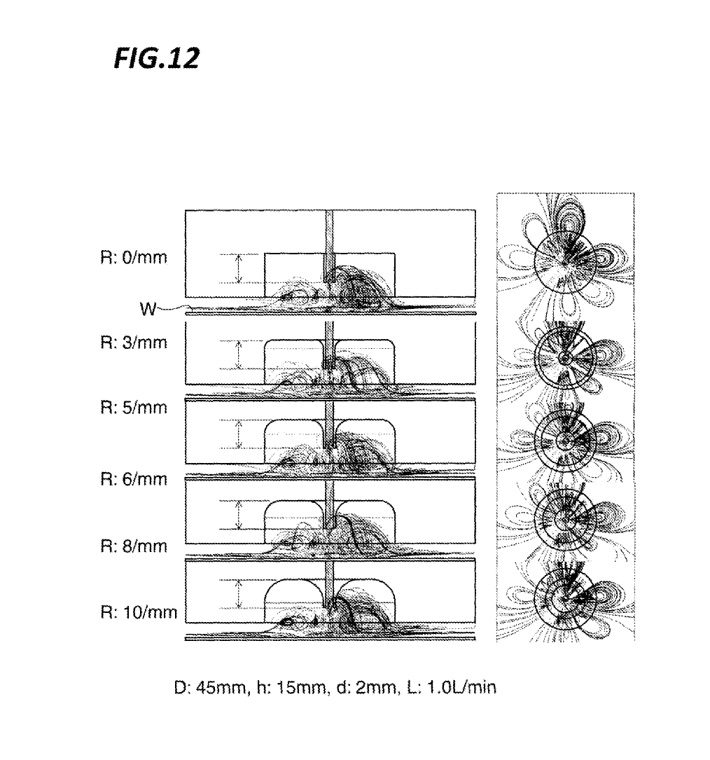

FIG. 12 illustrates a simulation result in which the protrusion height dh was set to 10 mm, and the curvature R was varied in a range of 0/mm to 10/mm. As compared with the simulation results of FIGS. 10 and 11, in the simulation result of FIG. 12, forming the curved faces 54 and 55 having the curvature R did not clearly show an effect on the generation of a vortex. From this, it is considered that even though forming the curved faces 54 and 55 facilitates the generation of a vortex, the degree of effect thereof relies on a set condition of the protrusion height dh.

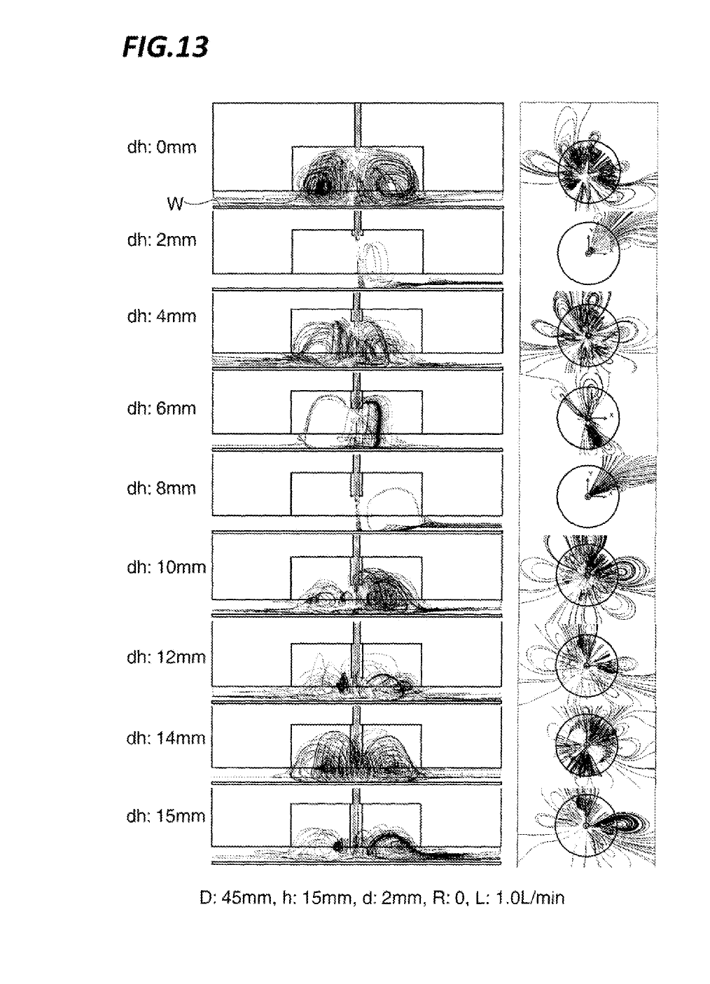

FIG. 13 illustrates a simulation result in which the protrusion height dh was varied in a range of 0 mm to 15 mm. The results obtained in the parameter conditions illustrated in FIG. 10 is that a favorable vortex having a low flow speed is generated when the protrusion height dh is 0 mm, 4 mm, 10 mm, and 14 mm. However, a clear relation between the protrusion height dh and formation of the vortex did not appear.

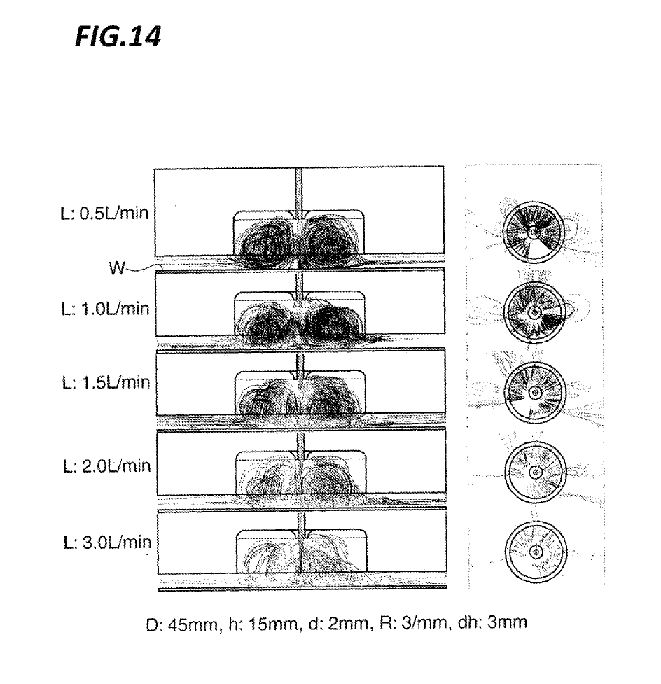

FIG. 14 illustrates a simulation result in which the flow rate of the purge gas was varied in a range of 0.5 L/min to 3 L/min. When the flow rate L of the purge gas is reduced, the flow speed of the purge gas is inevitably reduced. In FIG. 14, when the flow rate L of the purge gas increases, flows having a high flow speed increase within the vortex generating chamber 41. However, the flows do not appear in FIG. 14 due to the colors (yellow-yellow green) in the original drawing.

The result obtained in the parameter conditions set here is that although a vortex is generated when the flow rate L is in a range of 0.5 L/min to 3 L/min, in particular, a favorable vortex having a low flow speed is generated when the flow rate L is in a range of 0.5 L/min to 1.5 L/min, and the flow speed of the vortex increases and the density of flow speed lines of the gas is reduced when the flow rate L is in a range of 2.0 L/min to 3.0 L/min.

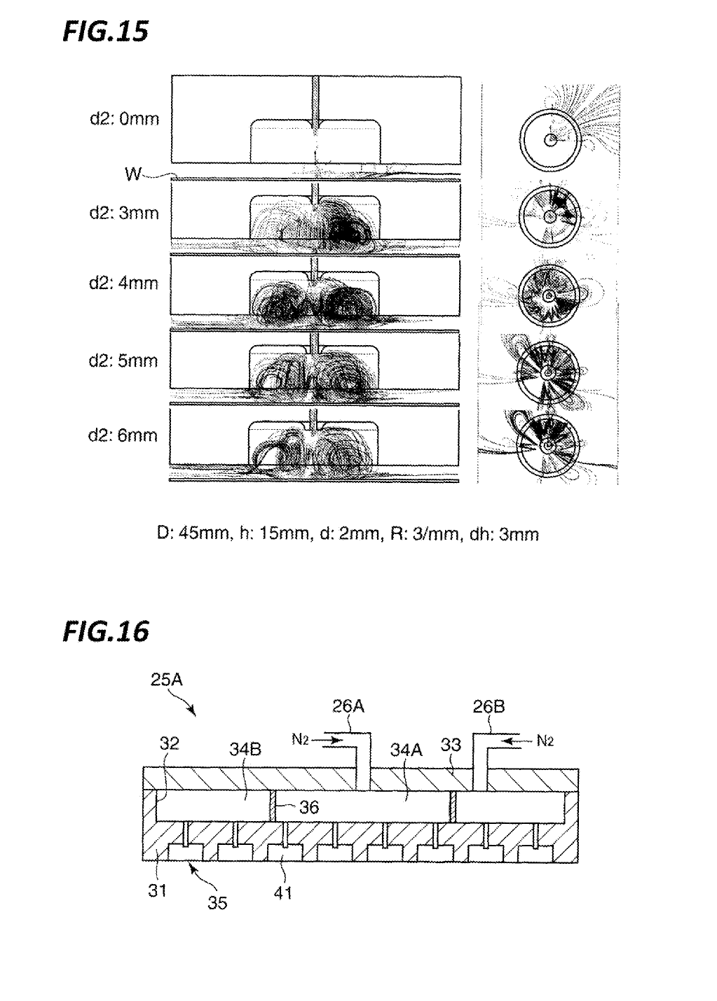

FIG. 15 illustrates a simulation result in which the protrusion diameter d2 was varied in a range of 2 mm to 6 mm. The result obtained in the parameter conditions illustrated in FIG. 15 is that a favorable vortex is generated when the protrusion diameter d2 is in the range of 3 mm to 5 mm, in particular, when the protrusion diameter d2 is set to 4 mm.

From the simulation results of FIGS. 6 to 15 described above, it has been shown that when the shape of the gas injection nozzle 35 is properly designed, a vortex is capable of being generated in the purge gas injected from the nozzle hole 42, and efficiently cooling the wafer W by heat exchange with the wafer W.

Meanwhile, a specific shape of the gas injection nozzle 35 is properly designed in consideration of, for example, an amount of gas to be introduced into a load-lock chamber 13 within a predetermined time, and a cooling rate of the wafer W in which a throughput in the entire plasma processing apparatus 10 is taken into consideration. For example, when the simulation results of FIG. 8 are taken into consideration, the shape may be designed such that, among the diameter D and depth h of the vortex generating chamber and the clearance CL, a relation of 1.63(=45/(22.5+5))<D/(h+CL)<2.57(=45/(12.5+5)), more particularly, 1.8(=45/(20+5))<D/(h+CL)<2.25(=45/(15+5)) is established, which may reduce the influence of other parameters exerted on the generation of the vortex of the purge gas, so that the generation of the vortex of the purge gas may be facilitated.

By reducing the thickness of the gas injection member 25, the weight reduction and cost reduction may be achieved and the load-lock chamber 13 may be configured compactly. However, when the thickness of the gas injection member 25 is reduced, it may be impossible to take the depth h of the vortex generating chamber 41 sufficiently. Thus, when the ratio of D/(h+CL) is to be set as described above, it is necessary to reduce the diameter D of the vortex generating chamber 41 as the height h is reduced. In such a case, for example, increasing the number of gas injection nozzles 35 to be formed in the disc member 31 or reducing the tube diameter d of the nozzle holes 42 may be needed.

As described above, in the present exemplary embodiment, when the gas purge gas is injected to the surface of a wafer W from the injection nozzles 35 so as to cool the wafer W, a vortex is generated in the purge gas to increase the number of times of impingement between the purge gas and the wafer W, and to perform heat exchange between the purge gas and the wafer W so that the wafer W may be efficiently cooled. At the same time, since the load-lock chamber 13 may be switched from a vacuum atmosphere to an atmospheric pressure atmosphere, the purge gas, which has been used only for switching the interior of the load-lock chamber 13 from the vacuum atmosphere to the atmospheric pressure atmosphere in the related art, may be effectively used. In addition, since a brake filter, which has been used in the related art, becomes needless, the costs of the plasma processing apparatus 10 may be reduced. Furthermore, since a water cooling apparatus, which includes a water cooling table and has been conventionally used for cooling a wafer W, becomes needless, the structure of the load-lock chamber 13 may be simplified to reduce the internal volume thereof. In this way, occurrence of trouble of water leakage may be reduced, and further, the costs of the plasma processing apparatus 10 may also be reduced.

FIG. 16 is a cross-sectional view schematically illustrating a configuration of a modified example of the gas injection member 25 of FIGS. 3A and 3B. In a gas injection member 25A, a cylindrical member 36 is disposed to serve as a partition within the buffer chamber 34 of the gas injection member 25 so that the buffer chamber 34 is divided two blocks of a first buffer chamber 34A in the central portion and a second buffer chamber 34B in the peripheral portion. In addition, the gas injection member 25A is configured such that the first buffer chamber 34A is supplied with a purge gas (e.g., N₂) from a gas supply tube 26A, and the second buffer chamber 34B is supplied with a purge gas (e.g., N₂) from the gas supply tube 26B.

In the gas injection member 25A, each of the gas flow rates supplied through the gas supply tubes 26A and 26B from the gas supply units (not illustrated) is adjusted, so that the gas flow rate injected from the nozzle holes 42 of the gas injection nozzles 35 communicated with the first buffer chamber 34A and the gas flow rate injected from the nozzle holes 42 of the gas injection nozzles 35 communicated with the second buffer chamber 34B may be independently controlled. For example, when a gas flow rate control is performed, for example, so as to increase the gas flow rate injected from the nozzles holes 42 facing the central portion of the wafer W which is hardly cooled and communicated with the first buffer chambers, to be higher than the gas flow rate injected from the nozzle holes 42 communicated with the second buffer chamber 34B, the in-plane uniformity of the wafer W in cooling may be enhanced.

Although the gas injection member 25A is configured to include the buffer chamber with two blocks of the first buffer chamber 34A and the second buffer chamber 34B, it is possible to employ a configuration in which more blocks are formed and gas supply is independently performed with respect to each of the blocks. In addition, it is possible to employ a configuration in which the gas flow rate injected from the nozzle holes 42 is controlled for each gas injection nozzle 35 without forming the buffer chamber. Then, by performing a more detailed gas flow rate control, the purge gas may be efficiently used to enhance the uniformity in cooling the wafer W.

In addition, the gas injection nozzles 35 are formed at regular intervals in the gas injection member 25 or 25A. Without being limited thereto, however, some of the plurality of gas injection nozzles 35 may be arranged at regular intervals but the other gas injection nozzles may be arranged at different intervals. In addition, some of the gas injection nozzles 35 may have a size which is different from that of the other gas injection nozzles.

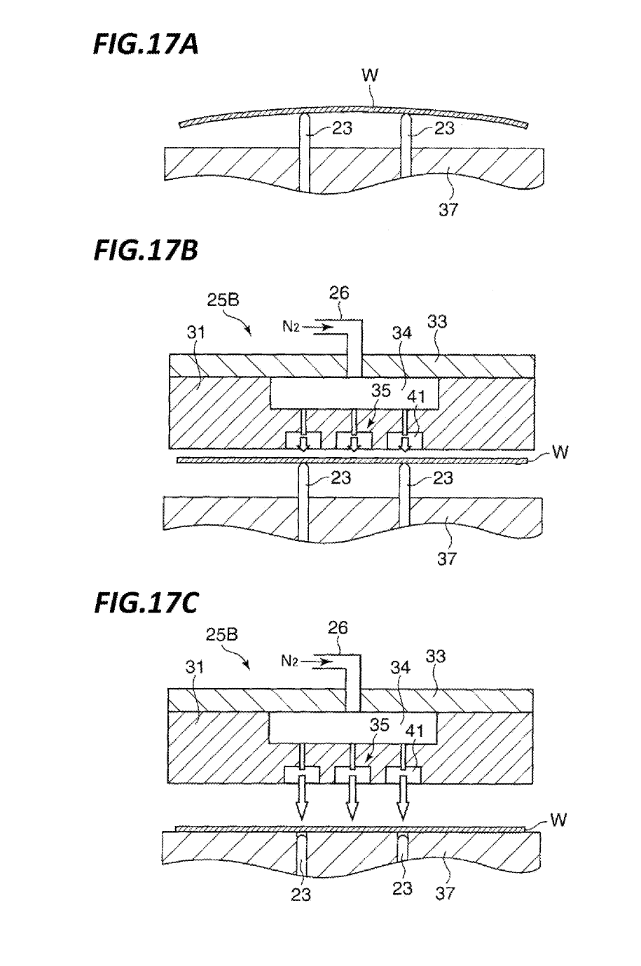

FIGS. 17A to 17C are cross-sectional views schematically illustrating a schematic configuration of another modified example of the gas injection member 25 of FIGS. 3A and 3B and a method of cooling a wafer. FIG. 17A illustrates a state in which a wafer W is carried into a load-lock chamber 13 and supported by lifting pins 23. The load-lock chamber 13 is provided with a placing table 37 on which the wafer W is placed, and the lifting pins 23 may take a state in which the lifting pins 23 protrude from the placing table 37, and a state in which the lifting pins 23 sink to the inside of the placing table 37.

Meanwhile, the lifting pins 23 are configured to hold the central side of the wafer W since the scalar robot 15 is configured to hold a portion in the vicinity of the outer periphery of the wafer W in consideration of delivery of the wafer W between the lifting pins 23 and the scalar robot 15 and in order to convey the wafer W processed in the vacuum processing chamber 12 in a stably held state without dropping the wafer W (see FIG. 1).

Especially, when the size of the wafer W is increased, the peripheral portion of the wafer W is apt to be sagged downwardly as compared to the central portion (in an upwardly convex arc shape) due to the self-weight of the wafer W, as illustrated in FIG. 17A. When the wafer W is placed on the placing table 37 in this state, the peripheral side of the wafer W is cooled more rapidly than the central side and the peripheral portion is contracted while the central portion of the wafer W is expanded. Thus the deflection of the wafer W may increase, the rear surface of the wafer W may be scratched, and a pattern (element) formed on the front surface of the wafer W may be damaged. For example, when the gas is supplied to the entire wafer W supported on the lifting pins 23 using the gas injection member 25 so as to cool the wafer W, the peripheral portion of the wafer W may be cooled more easily than the central portion. Thus, the peripheral portion of the wafer W is contracted while the central portion is expanded, which may cause the deflection of the wafer W to increase.

Thus, as illustrated in FIG. 17B, a gas injection member 25B has a structure in which the gas injection nozzles 35 are provided only in a region facing the central portion of the wafer W. The gas is injected to the central portion of the wafer, which is hardly cooled, from the gas injection nozzles 35 so as to assist the cooling of the central portion of the wafer W. The gas injection from the gas injection nozzle 35 of the gas injection member 25B is rapidly performed after the wafer W is supported by lifting pins 23, the scalar robot 15 retreats from the load-lock chamber 13, and the load-lock chamber 13 is sealed. Thus, the deflection of the wafer W may be suppressed from increasing or reduced. Specifically, the central portion of the wafer W is set to have a radius within one half of the radius of the wafer W from the center of the wafer W.

Here, when the gas is supplied only to the central portion of the wafer W to cool the wafer W, the cooling rate of the wafer W is reduced with just that. Thus, the placing table 37 is provided in the load-lock chamber 13. As illustrated in FIG. 17C, in a state where the gas injection from the gas injection nozzles 35 of the gas injection member 25B is continued, the lifting pins 23 are lowered so as to place the wafer W on the placing table 37 so that the wafer W may be cooled using heat transfer from the wafer W to the placing table 37. In this way, the wafer W may be uniformly cooled to suppress occurrence of a temperature distribution in the plane of the wafer W and hence to suppress the deformation of the wafer W. At this time, in order to further enhance the cooling efficiency, the placing table 37 may be configured to have a water cooling structure.

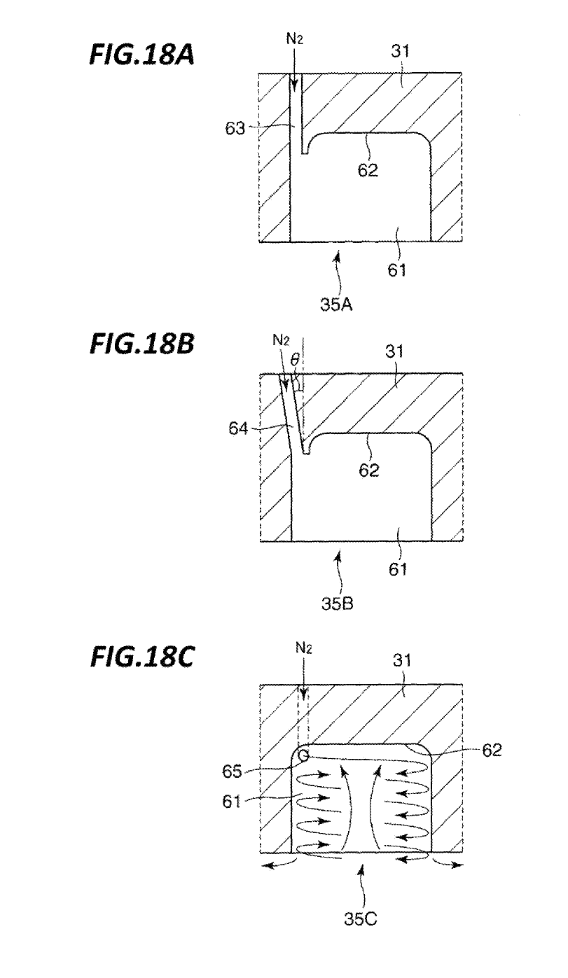

Meanwhile, the wafer W cooling method illustrated in FIGS. 17B and 17C may be executed by performing gas injection only from the first buffer chamber 34A using the gas injection member 25A instead of the gas injection member 25B. In addition, although it has been described that the gas injection member 25B is provided with the gas injection nozzles 35, the gas injection nozzles 35 may be replaced by gas injection nozzles 35C to be described below with reference to FIG. 18C. When the gas injection nozzles 35 are used, the in-plane temperature uniformity of the wafer W may be enhanced as compared to the case where the gas injection nozzles 35C are used. Meanwhile, it has been found that when the gas injection nozzles 35C are used, the cooling rate can be increased as compared to the case where the gas injection nozzles 35 are used.

FIGS. 18A to 18C are cross-sectional views illustrating a schematic configuration of a modified example of the gas injection nozzle 35 of FIG. 4. In a gas injection nozzle 35A illustrated in FIG. 18A, a cylindrical vortex generating chamber 61 is formed to be opened in the bottom of the disc member 31, the opening position of the nozzle hole 63 is provided in the outer periphery of the bottom wall 62 of the vortex generating chamber 61. The cross-sectional shape of the injection nozzle 35A is equal to that of the right half of the cross-sectional shape of the gas injection nozzle 35 illustrated in the cross-sectional view of FIG. 4. Thus, in the gas injection nozzle 35A, the ratio of D/(h+CL) described above may be set to about 1. With this arrangement, it becomes easy to generate a vortex in the purge gas injected from the nozzle hole 63 within the vortex generating chamber 61.

In the gas injection nozzle 35A of FIG. 18A, the nozzle hole 63 is formed such that the longitudinal direction of the nozzle hole 63 is parallel with the vertical direction orthogonal to the bottom wall 62 of the vortex generating chamber 61. Whereas, in the gas injection nozzle 35B illustrated in FIG. 18B, the nozzle hole 64 is formed such that its longitudinal direction is deviated from the direction orthogonal to the bottom wall 62 of the vortex generating chamber 61 by an angle θ. Even with this structure, a vortex may be generated in the purge gas injected from the nozzle hole 63 within the vortex generating chamber 61.

A gas injection nozzle 35C of FIG. 18C is provided with a nozzle hole 65 configured to inject the purge gas in a direction which is substantially parallel with the bottom wall 52 so as to form a spiral vortex along the side wall of the vortex generating chamber 61. The spiral vortex is generated in the purge gas injected from the nozzle hole 65, and flows circulating toward the center of the bottom wall 62 from the surface of the wafer W are generated which may increase the number of times of impingement of the purge gas against the wafer W to facilitate heat exchange.

Meanwhile, as a modified example of the gas injection nozzle 35C, even with a configuration in which a nozzle is provided in the bottom face of the disc member 31 to inject the purge gas such that a spiral vortex is formed in the clearance between the bottom face of the disc member 31 and the wafer W without forming the vortex generating chamber 61, the load-lock chamber 13 may be switched from the vacuum atmosphere to the atmospheric pressure atmosphere while cooling the wafer W by the swirl vortex.

Although the exemplary embodiments of the present disclosure have been described above, the present disclosure is not limited thereto. For example, in the exemplary embodiments described above, a plasma processing apparatus is exemplified as the substrate processing apparatus. Without being limited thereto, however, the present disclosure may be applied to a substrate processing apparatus including a substrate processing chamber in which a processing of increasing a substrate temperature is performed on a substrate, and an intermediate conveyance chamber of which the interior may be switched between a vacuum atmosphere and an atmospheric pressure atmosphere in order to convey the substrate processed in the substrate processing chamber to the outside which is under the atmospheric pressure. That is, the gas injection member 25 may be disposed in the intermediate conveyance chamber provided in the substrate processing apparatus.

In addition, in the above-described exemplary embodiments, it has been described that the wafer W supported on the lifting pins 23 is cooled by supplying the purge gas from the gas injection member 25 to the wafer W. However, a placing table, on which the wafer W is placed, may be provided in the load-lock chamber 13 in order to stabilize the posture of the wafer W during the cooling processing, and cooling by the gas injection member 25 may be performed in the state where the wafer W is supported on the placing table. At this time, when, for example, a water cooling table, which is excellent in cooling capability, is used as the placing table, the cooling action by the water cooling table and the cooling action by the gas injection member 25 may be combined with each other to increase the cooling rate, thereby cooling the wafer W with a high speed.

In the above-described exemplary embodiments, it has been described that a processed substrate is cooled in a vacuum atmosphere. However, the gas injection member 25 may be used even in a substrate processing apparatus that performs a cooling processing, under the atmospheric pressure, on a substrate which has been heated by a processing performed under the atmospheric pressure. Even in this case, as compared with a structure employing a conventional water cooling table, it is advantageous in that trouble such as water leakage does not occur, the apparatus structure may be simplified to enhance flexibility in designing the apparatus, and the apparatus costs may be reduced.

In the above-described exemplary embodiments, a semiconductor wafer is exemplified as the substrate. Without being limited thereto, however, the object to be cooled by the gas injection member 25 may be any other substrate such as, for example, a glass substrate for a flat panel display (FPD) or a ceramic substrate.

The application is based on and claims priority from Japanese Patent Application Nos. 2012-245360 and 2013-122587, filed on Nov. 7, 2012 and Jun. 11, 2013, with the Japan Patent Office, the disclosures of which are incorporated herein in their entirety by reference.

Descriptions of Symbols

| | |
|---|---|
| 10: plasma processing apparatus | 11: vacuum conveyance chamber |
| 13: load-lock chamber | 14: loader module |
| 23: lifting pin | 25, 25A, 25B: gas injection member |
| 26: gas supply tube | 31: disc member |
| 32: recess | 33: cover member |
| 34, 34A, 34B: buffer chamber | 35, 35A to 35C: gas injection nozzle |
| 41, 61: vortex generating chamber | 42, 63 to 65: nozzle hole |

51: side wall (of vortex generating chamber)
52: bottom wall (of vortex generating chamber)

| | |
|---|---|
| 54, 55: curved face | W: semiconductor wafer |

1. A substrate cooling member comprising:
a plurality of gas injection nozzles formed on one flat plate face of the substrate cooling member which has a flat plate shape, the plurality of gas injection nozzles being configured to inject a gas toward a substrate so as to cool the substrate,
wherein each of the plurality of gas injection nozzles includes:
a cylindrical space which is opened in the one flat plate face of the substrate cooling member; and
a nozzle hole which is opened in a circular bottom wall that defines the space, to inject the gas toward the space, and
wherein, when the gas is injected toward the substrate from the nozzle hole through the space in a state where the one flat plate face, which is formed with the plurality of gas injection nozzles in the substrate cooling member, faces a flat plate face of the substrate, a swirling flow is generated in the gas injected from the nozzle hole within the space so as to cool the substrate.

2. The substrate cooling member of claim 1, wherein the gas injected from the nozzle hole generates a flow swirling in a plane orthogonal to the one flat plate face in the space.

3. The substrate cooling member of claim 1, wherein the nozzle hole injects the gas in a direction substantially orthogonal to the bottom wall that defines the space.

4. The substrate cooling member of claim 1, wherein a portion where a side wall and the bottom wall that define the space intersect with each other is formed as a curved face having a predetermined curvature.

5. The substrate cooling member of claim 1, wherein a protrusion is formed at a center of the circular bottom wall that defines the space to protrude to the space, and the nozzle hole is opened in the protrusion.

6. The substrate cooling member of claim 5, wherein a portion where the bottom wall that defines the space and a side wall of the protrusion intersect with each other is formed as a curved face having a predetermined curvature.

7. The substrate cooling member of claim 1, wherein, assuming that a diameter of the space is D, a depth of the space is h, and a clearance between the one flat plate face formed with the gas injection nozzle and the flat plate face of the substrate is CL, a relation of 1.63<D/(h+CL)<2.57 is achieved.

8. The substrate cooling member of claim 1, wherein the substrate cooling member includes a buffer chamber communicated with the nozzle holes, and a gas supplied to the buffer chamber is injected from the nozzle holes.

9. The substrate cooling member of claim 8, wherein the buffer chamber is divided to a plurality of blocks by a partition, and gas support ports are formed to independently supply a gas to the plurality of blocks, respectively.

10. The substrate cooling member of claim 9, wherein the plurality of blocks are a first block facing a central portion of the substrate and a second block provided in outer periphery of the first block.

11. The substrate cooling member of claim 1, wherein the plurality of gas injection nozzles are provided in a region facing a central portion of the substrate.

12. A substrate processing apparatus comprising:
a substrate processing chamber in which a predetermined processing accompanying a substrate temperature rise is performed on a substrate; and
a substrate cooling chamber in which the substrate processed in the substrate processing chamber is cooled,
wherein the substrate cooling chamber includes:
a support member configured to support the substrate, and
a substrate cooling member including a plurality of gas injection nozzles formed on one flat plate face of the substrate cooling member which has a flat plate shape, the plurality of gas injection nozzles being configured to inject a gas toward the substrate supported on the support member to cool the substrate,
wherein each of the plurality of gas injection nozzles includes:
a cylindrical space which is opened in the one flat plate face of the substrate cooling member, and
a nozzle hole which is opened in a circular bottom wall that defines the space, to inject the gas toward the space, and
wherein, when the gas is injected toward the substrate from the nozzle hole through the space in a state where the one flat plate face, which is formed with the plurality of gas injection nozzles in the substrate cooling member, faces a flat plate face of the substrate, a swirling flow is generated in the gas injected from the nozzle hole within the space so as to cool the substrate.

13. The substrate processing apparatus of claim 12, wherein the substrate cooling chamber is configured such that an interior of the substrate cooling chamber is configured to be selectively switched to an atmospheric pressure atmosphere or a vacuum atmosphere, so as to convey the substrate between a processing chamber which is under a vacuum atmosphere and a processing chamber which is under the atmospheric pressure atmosphere, and
the substrate cooling member is configured to inject a gas, which is introduced into the substrate cooling chamber in order to switch the substrate cooling chamber from the vacuum atmosphere to the atmospheric pressure atmosphere, from the plurality injection nozzles to cool the substrate.

14. The substrate processing apparatus of claim 13, wherein the processing chamber which is under the vacuum atmosphere is the substrate processing chamber or a first substrate conveyance chamber disposed between the substrate processing chamber and the substrate cooling chamber in which a first conveyance apparatus is disposed to convey the substrate between the processing chamber and the substrate cooling chamber, and
the processing chamber which is under the atmospheric pressure atmosphere is a second substrate conveyance chamber in which a second conveyance apparatus is disposed to convey the substrate between a container accommodating the substrate and the substrate cooling chamber.

15. A substrate processing apparatus comprising:
a substrate processing chamber maintained under a vacuum atmosphere, and configured to perform a predetermined processing accompanying a substrate temperature rise on a substrate accommodated therein;
a substrate carry-in chamber maintained under an atmospheric pressure atmosphere, the substrate to be processed in the substrate processing chamber being carried into the substrate carry-in chamber from outside; and
an intermediate conveyance chamber having an interior configured to be selectively switched to the atmospheric pressure atmosphere or the vacuum atmosphere so as to carry the substrate between the processing chamber which is under the vacuum atmosphere and the substrate carry-in chamber which is under the atmospheric pressure atmosphere,
wherein the intermediate conveyance chamber includes:
a support member configured to support the substrate;
a substrate cooling member including a plurality of gas injection nozzles formed on one flat plate face of the substrate cooling member which has a flat plate shape, the plurality of gas injection nozzles being configured to inject a gas toward a substrate supported on the support member,
wherein each of the plurality of gas injection nozzles includes:
a cylindrical space which is opened in the one flat plate face of the substrate cooling member, and
a nozzle hole which is opened in a circular bottom wall that defines the space, to inject the gas toward the space, and
wherein, when the gas is injected toward the substrate from the nozzle hole through the space in a state where the one flat plate face, which is formed with the plurality of gas injection nozzles in the substrate cooling member, faces a flat plate face of the substrate, a swirling flow is generated in the gas injected from the nozzle hole within the space so as to cool the substrate, and at the same time, the intermediate conveyance chamber is switched from the vacuum atmosphere to the atmospheric pressure atmosphere.

16. The substrate processing apparatus of claim 15, wherein the substrate processing chamber is a plasma processing chamber configured to perform a plasma processing on the substrate.

17. The substrate processing apparatus of claim 12, wherein the gas injected from the nozzle hole generates a flow swirling in a plane orthogonal to the one flat plate face in the space.

18. The substrate processing apparatus of claim 12, wherein the nozzle hole injects the gas in a direction substantially orthogonal to the bottom wall that defines the space.

19. The substrate processing apparatus of claim 12, wherein each of the plurality of gas injection nozzles includes a protrusion formed to protrude to the space at a center of the circular bottom wall that defines the space, and the nozzle hole is opened in the protrusion.

20. The substrate processing apparatus of claim 12, wherein, assuming that a diameter of the space is D, a depth of the space is h, and a clearance between the one flat plate face formed with the gas injection nozzle and the flat plate face of the substrate is CL, a relation of 1.63<D/(h+CL)<2.57 is achieved.

21. The substrate processing apparatus of claim 12, wherein the substrate cooling member includes a buffer chamber communicated with the nozzle holes, and a gas supplied to the buffer chamber is injected from the nozzle holes.

22. The substrate processing apparatus of claim 21, wherein the buffer chamber is divided to a plurality of blocks by a partition, and gas support ports are formed to independently supply a gas to the plurality of blocks, respectively.

23. The substrate processing apparatus of claim 22, wherein the plurality of blocks are a first block facing a central portion of the substrate and a second block provided in outer periphery of the first block.

24. The substrate processing apparatus of claim 22, wherein the buffer chamber is divided into a plurality of blocks and a gas supply unit configured to control a gas flow rate supplied to the plurality of blocks is provided such that a flow speed of the gas injected from the gas injection nozzles facing the central portion of the substrate supported on the support member among the plurality of gas injection nozzles is different from a flow rate of a gas injected from the gas injection nozzles facing the peripheral portion of the substrate.

25. The substrate processing apparatus of claim 12, wherein the plurality of gas injection nozzles are provided in a region facing a central portion of the substrate.

26. The substrate processing apparatus of claim 12, wherein the flat plate face of the substrate cooling member has a size substantially equal to a size of the flat plate face of the substrate supported on the support member.

27. A substrate processing method that cools a substrate by injecting a gas toward the substrate from a plurality of gas injection nozzles using a substrate cooling member including the plurality of gas injection nozzles formed on one flat plate face of the substrate cooling member which has a flat plate shape, wherein the gas is injected toward the substrate from the gas injection nozzles in a state where the one flat plate face, which is formed with the plurality of gas injection nozzles in the substrate cooling member, faces a flat plate face of the substrate, and a swirling flow is generated in the gas in a plane orthogonal to the flat plate face of the substrate to cool the substrate.

28. The substrate processing method of claim 27, wherein a cylindrical space is formed such that the plurality of gas injection nozzles are opened in the one flat plate face of the substrate cooling member, and the plurality of gas injection nozzles are opened in a circular bottom wall defining the space to form nozzles holes that inject the gas toward the space such that the swirling flow is generated in the space.

29. The substrate processing method of claim 27, wherein the gas is injected toward the substrate from the plurality of gas injection nozzles using the substrate cooling member which is provided with the plurality of gas injection nozzles in a region facing a central portion of the substrate.

30. The substrate processing method of claim 29, wherein the central portion of the substrate has a radius within a range of ½ of a radius of the substrate from a center of the substrate.

31. The substrate processing method of claim 27, wherein the substrate cooling member is disposed within a processing chamber configured to be selectively switched to an atmospheric pressure atmosphere or vacuum atmosphere, and the gas is injected from the plurality of gas injection nozzles in the processing chamber which is under the vacuum atmosphere so that the substrate is cooled and at the same time, an interior of the processing chamber is switched to the atmospheric pressure atmosphere.

32. The substrate processing method of claim 31, wherein, while the gas is injected from the plurality of gas injection nozzles toward the substrate in a state where the substrate is supported on a support member provided in the processing chamber, the support member is moved down into a cooling table provided in the processing chamber so that the substrate is placed on the cooling table to be cooled.

33. The substrate processing method of claim 32, wherein cooling water is circulated in the cooling table.
